(19) United States
(12) Patent Application Publication
(10) Pub. No.: US 2024/0127901 A1
(43) Pub. Date: Apr. 18, 2024

(54) TEMPERATURE-BASED ERROR MASKING DURING MBIST OPERATION

(71) Applicant: Micron Technology, Inc., Boise, ID (US)

(72) Inventors: Daniel S. Miller, Boise, ID (US); Yoshinori Fujiwara, Boise, ID (US)

(21) Appl. No.: 17/968,717

(22) Filed: Oct. 18, 2022

(51) Int. Cl. G11C 29/46; G11C 29/12; G11C 29/44

(52) U.S. Cl. CPC G11C 29/46; G11C 29/12015; G11C 29/44; G11C 2029/4402

(57) ABSTRACT

Methods, apparatuses, and systems related to masking of self-test results are described. A memory device may include a self-test circuit that is configured to selectively suspend collection of test results from one or more portions of a self-test when a temperature of the memory device exceeds a temperature threshold.

### TECHNICAL FIELD

The present disclosure is related to devices, and in particular semiconductor memory devices with temperature-based error masking during memory built-in self-test (mBIST) operation.

### BACKGROUND

An apparatus (e.g., a processor, a memory system, and/or other electronic apparatus) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but rather are for explanation and understanding only.

FIG. 1 is a block diagram schematically illustrating a memory device, in accordance with embodiments of the present technology.

FIG. 2 is a block diagram of a system having a memory device configured, in accordance with embodiments of the present technology.

FIG. 3 is a simplified block diagram schematically illustrating a temperature-based masking circuit, in accordance with embodiments of the present technology.

FIG. 4 is a flow diagram illustrating a process for masking errors, based on temperature, during mBIST operation, in accordance with embodiments of the present technology.

FIG. 5 is a waveform diagram illustrating error masking during an mBIST operation, in accordance with embodiments of the present technology.

FIG. 6 is a schematic view of a system that includes an apparatus, in accordance with embodiments of the present technology.

### DETAILED DESCRIPTION

As described in greater detail below, the technology disclosed herein relates to an apparatus, such as for memory systems, a system with memory devices, related methods, etc., for masking certain errors generated during diagnostic operations (e.g., self-tests) performed during the lifetime of the apparatus. The apparatus can include a diagnostic mechanism to perform diagnostic operations, such as a memory built-in self-test (mBIST) mechanism (e.g., circuits, software instructions, firmware, or a combination thereof), configured to test and evaluate an internal storage circuit and/or operations regarding the same. For example, the mBIST mechanism can perform a sequence of reads and writes to a memory array according to a predetermined self-test sequence. The mBIST mechanism can store the test results at designated locations, such as in error latches or other state-storing devices, for subsequent access and/or evaluation. For example, test results stored in error latches can be used to perform on-die repairs of the memory array.

The diagnostic operations, including mBIST, may be performed while the apparatus is subjected to various conditions, including high temperatures (e.g., ambient temperatures exceeding 125° C.). However, the behavior of components of the apparatus, such as the memory array, may change and/or generate unexpected results depending on those conditions. For example, at high temperatures, the retention time of a DRAM (i.e., the time a DRAM cell can retain its stored value before requiring a refresh of the cell's content) is significantly reduced. Furthermore, mBIST operations may not be able to satisfy the reduced retention time caused by high temperatures (e.g., the time between mBIST-controlled accesses to the memory array to test the array's functionality, such as a write-to followed by a read from a DRAM cell, may exceed the retention time).

Thus, a conventional mBIST mechanism operating while the apparatus is subject to high temperatures may store test results that indicate memory array failures, when the observed failures are likely the result of the operating conditions and reduced retention rate, and not necessarily indicative of a defect in the memory array itself. That is, a conventional device and mBIST mechanism operating under high temperature may overstate the number of failures in the memory array, and unnecessarily allocate the limited on-die repair resources of the memory array to failures caused by high temperatures (and which may not be present when the device is within typical operating conditions). As a result, these on-die repair resources may not be available for other failures (e.g., failures caused by a defect or other unexpected behavior observed at typical operating conditions) that present themselves later in the lifetime of the conventional device, therefore requiring the use of post-package repair (PPR) to correct.

In contrast to the conventional devices, the apparatus described herein can include a temperature-based mBIST error masking mechanism that prevents the recording of mBIST failures when the apparatus is performing mBIST operations at high temperatures. For example, in some embodiments, the apparatus can include one or more temperature sensors that sense the temperature of the apparatus. The temperature-based mBIST error masking mechanism can use data from the one or more temperature sensors to detect when the apparatus is operating outside of typical temperatures, and mask any errors detected during mBIST operations accordingly. For example, as described herein, the temperature-based mBIST error masking mechanism can prevent the error latches from storing mBIST test results (such as failure address information) when the sensed temperature exceeds a threshold. In some embodiments, the error latches are held in a reset state for the duration of mBIST operations once a temperature exceeding a threshold is detected. As such, the apparatus can prevent the unnecessary allocation of on-die repair resources to failures caused by high temperatures.

### Example Environment

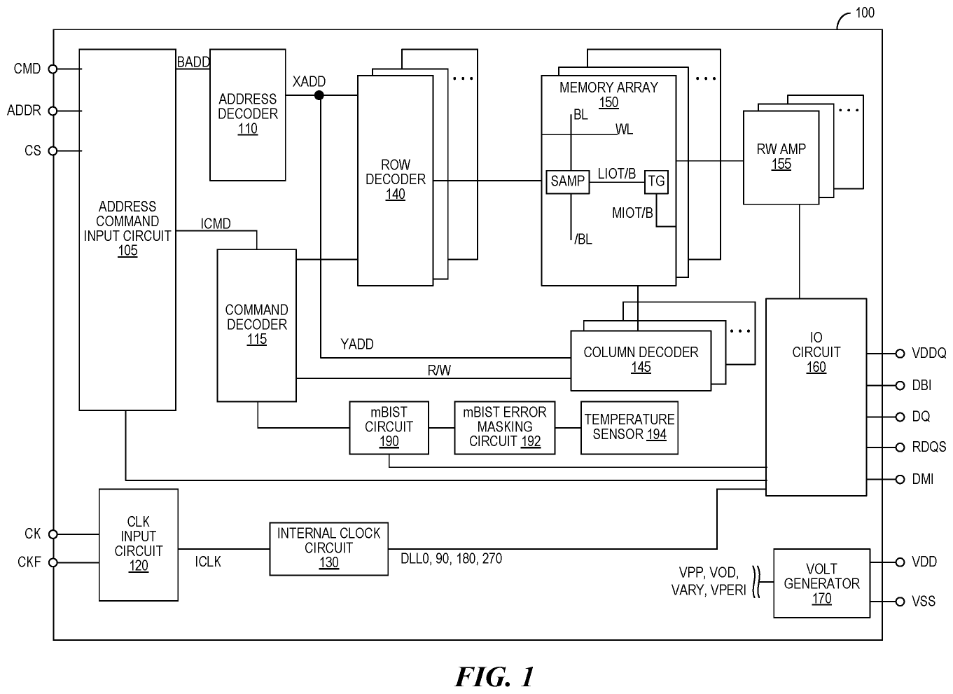

FIG. 1 is a block diagram of an apparatus 100 (e.g., a semiconductor die assembly, including a three-dimensional integration (3DI) device or a die-stacked package) in accordance with an embodiment of the present technology. For example, the apparatus 100 can include a DRAM or a portion thereof that includes one or more dies/chips.

The apparatus 100 may include an array of memory cells, such as memory array 150. The memory array 150 may include a plurality of banks (e.g., banks 0-15), and each bank may include a plurality of word lines (WL), a plurality of bit lines (BL), and a plurality of memory cells arranged at intersections of the word-lines and the bit lines. Memory cells can include any one of a number of different memory media types, including capacitive, magnetoresistive, ferroelectric, phase change, or the like. The selection of a word-line WL may be performed by a row decoder 140, and the selection of a bit line BL may be performed by a column decoder 145. Sense amplifiers (SAMP) may be provided for corresponding bit lines BL and connected to at least one respective local input/output (IO) line pair (LIOT/B), which may in turn be coupled to at least a respective one main IO line pair (MIOT/B), via transfer gates (TG), which can function as switches. The sense amplifiers and transfer gates may be operated based on control signals from decoder circuitry, which may include the command decoder 115, the row decoders 140, the column decoders 145, any control circuitry of the memory array 150, or any combination thereof. The memory array 150 may also include plate lines and corresponding circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data clock terminals to receive data clock signals WCK and WCKF, data terminals DQ, RDQS, DBI, and DMI, and power supply terminals VDD, VSS, and VDDQ.

The command terminals and address terminals may be supplied with an address signal and a bank address signal (not shown in FIG. 1) from outside. The address signal and the bank address signal supplied to the address terminals can be transferred, via a command/address input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller and/or a nefarious chipset. The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded, and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word-line and a column command signal to select a bit line. The command decoder 115 may further include one or more registers for tracking various counts or values (e.g., counts of refresh commands received by the apparatus 100 or self-refresh operations performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1). The read latency information RL can be defined in terms of clock cycles of the CK clock signal. For example, the read latency information RL can be a number of clock cycles of the CK signal after the read command is received by the apparatus 100 when the associated read data is provided.

Write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160 and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register. The write latency WL information can be defined in terms of clock cycles of the CK clock signal. For example, the write latency information WL can be a number of clock cycles of the CK signal after the write command is received by the apparatus 100 when the associated write data is received.

The power supply terminals may be supplied with power supply potentials VDD and Vss. These power supply potentials VDD and VSS can be supplied to an internal voltage generator circuit 170. The internal voltage generator circuit 170 can generate various internal potentials VPP, VOD, VARY, VPERI, and the like, based on the power supply potentials VDD and VSS. The internal potential VPP can be used in the row decoder 140, the internal potentials VOD and VARY can be used in the sense amplifiers included in the memory array 150, and the internal potential VPERI can be used in many other circuit blocks.

The power supply terminal may also be supplied with power supply potential VDDQ. The power supply potential VDDQ can be supplied to the input/output circuit 160 together with the power supply potential VSS. The power supply potential VDDQ can be the same potential as the power supply potential VSS in an embodiment of the present technology. The power supply potential VDDQ can be a different potential from the power supply potential VDD in another embodiment of the present technology. However, the dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable (not shown in FIG. 1) from the command/address input circuit 105. For example, the internal clock circuit 130 can include a clock path (not shown in FIG. 1) that receives the internal clock signal ICLK and provides various clock signals to the command decoder 115. The internal clock circuit 130 can further provide input/output (IO) clock signals. The IO clock signals can be supplied to the input/output circuit 160 and can be used as timing signals for determining output timing of read data and/or input timing of write data. The IO clock signals can be provided at multiple clock frequencies so that data can be output from and input to the apparatus 100 at different data rates. A higher clock frequency may be desirable when high memory speed is desired. A lower clock frequency may be desirable when lower power consumption is desired. The internal clock signals ICLK can also be supplied to a timing generator 135 and thus various internal clock signals can be generated.

The apparatus 100 can be connected to any one of a number of electronic devices capable of utilizing memory for the temporary or persistent storage of information, or a component thereof. For example, a host device of apparatus 100 may be a computing device, such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 100; although in other embodiments, the host device may be indirectly connected to a memory device (e.g., over a networked connection or through intermediary devices).

The apparatus 100 can include diagnostic mechanism self-test circuits, such as mBIST circuit 190 and/or mBIST error masking circuit 192. The apparatus can additionally include a temperature sensor 194. The mBIST circuit 190 can be configured to implement and/or control self-test (e.g., built-in self-test (BIST)) to evaluate a functional circuit (e.g., the memory array 150 and/or one or more other circuits described above) and a corresponding set of functions. For example, the mBIST circuit 190 can be configured to perform a sequence of writes to and reads from the memory array 150. The mBIST circuit 190 can store the test results (e.g., results indicating whether data read from the memory array 150 matches the results expected based on data written to the memory array and/or the addresses in the memory array of any mismatches) in one or more error latches (not shown). The one or more error latches can be configured to use the stored test results to configure on-die repair resources and/or to output the rest results (e.g., by providing the test results via terminals of the apparatus 100 and/or by writing to a status register the contents of which are accessible via terminals of the apparatus).

During operation of a self-test (e.g., by mBIST circuit 190), the mBIST error masking circuit 192 can disable the recording of test results by the mBIST circuit 190, thereby “masking” any errors identified by the self-test, depending on the conditions of the apparatus 100. For example, the mBIST error masking circuit 192 can receive temperature data from the temperature sensor 194 that characterizes the temperature of the apparatus 100. The mBIST error masking circuit 192 can evaluate the temperature data to determine whether the temperature of the apparatus 100 exceeds a threshold temperature. If the temperature data from the temperature sensor 194 indicates that the temperature of the apparatus 100 exceeds a threshold temperature, the mBIST error masking circuit 192 can inhibit the error latches (not shown) of the mBIST circuit 190 from storing the test results. For example, the mBIST error masking circuit 192 can generate a signal (e.g., ClrErrLatch) that will force the error latches to be cleared and/or disabled. In some embodiments, the generation of the ClrErrLatch signal by the mBIST error masking circuit 192 is based further on an evaluation of whether the temperature data from the temperature sensor 194 is stable. In some embodiments, once the ClrErrLatch signal has been asserted (to clear and/or disable the error latches), it remains asserted until mBIST operations ended. Details regarding the mBIST circuit 190, mBIST error masking circuit 192, and temperature sensor 194 are described further below.

Although FIG. 1 illustrates an embodiment of the apparatus 100 in which the mBIST circuit 190, mBIST error masking circuit 192, and temperature sensor 194 are illustrated as different components, in some embodiments, one or more of the aforementioned circuits and/or sensors can be combined. For example, in some embodiments, the mBIST circuit 190 and mBIST error masking circuit 192 are a single circuit that performs both mBIST self-test and error masking functions. Although FIG. 1 illustrates an embodiment of the apparatus 100 with a single temperature sensor 194, in some embodiments, the apparatus includes multiple temperature sensors.

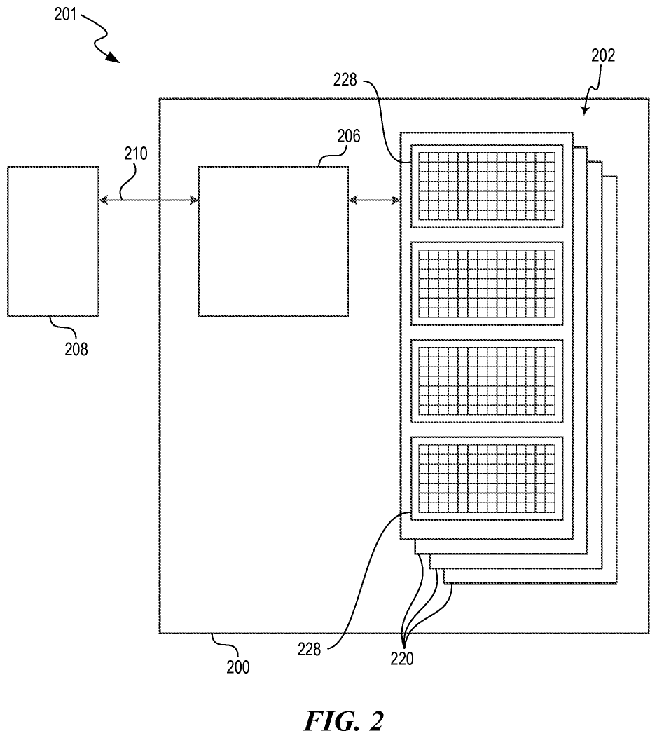

FIG. 2 is a block diagram of a system 201 having a memory device 200 configured in accordance with embodiments of the present technology. The memory device 200 may be an example of or include aspects of the memory device described with reference to FIG. 1. As shown, the memory device 200 includes a main memory 202 (e.g., DRAM, NAND flash, NOR flash, FeRAM, phase change memory (PCM), etc.) and control circuitry 206 operably coupled to a host device 208 (e.g., an upstream central processor (CPU), a memory controller). The control circuitry 206 may include aspects of various components described with reference to FIG. 1. For example, the control circuitry 206 may include aspects of the command/address input circuit 105, the address decoder 110, and the command decoder 115, among others.

The main memory 202 includes a plurality of memory units 220, which each include a plurality of memory cells. The memory units 220 can be individual memory dies, memory planes in a single memory die, a stack of memory dies vertically connected with through-silicon vias (TSVs), or the like. For example, in one embodiment, each of the memory units 220 can be formed from a semiconductor die and arranged with other memory unit dies in a single device package. In other embodiments, multiple memory units 220 can be co-located on a single die and/or distributed across multiple device packages. The memory units 220 may, in some embodiments, also be sub-divided into memory regions 228 (e.g., banks, ranks, channels, blocks, pages, etc.).

The memory cells can include, for example, floating gate, charge trap, phase change, capacitive, ferroelectric, magnetoresistive, and/or other suitable storage elements configured to store data persistently or semi-persistently. The main memory 202 and/or the individual memory units 220 can also include other circuit components, such as multiplexers, decoders, buffers, read/write drivers, address registers, data out/data in registers, etc., for accessing and/or programming (e.g., writing) the memory cells and other function, such as for processing information and/or communicating with the control circuitry 206 or the host device 208. Although shown in the illustrated embodiments with a certain number of memory cells, rows, columns, regions, and memory units for purposes of illustration, the number of memory cells, rows, columns, regions, and memory units can vary, and can, in other embodiments, be larger or smaller in scale than shown in the illustrated examples. For example, in some embodiments, the memory device 200 can include only one memory unit 220. Alternatively, the memory device 200 can include two, three, four, eight, ten, or more (e.g., 16, 32, 64, or more) memory units 220. Although the memory units 220 are shown in FIG. 2 as including four memory regions 228 each, in other embodiments, each memory unit 220 can include one, two, three, eight, or more (e.g., 16, 32, 64, 100, 128, 256, or more) memory regions.

In one embodiment, the control circuitry 206 can be provided on the same die as the main memory 202 (e.g., including command/address/clock input circuitry, decoders, voltage and timing generators, IO circuitry, etc.). In another embodiment, the control circuitry 206 can be a microcontroller, special purpose logic circuitry (e.g., a field programmable gate array (FPGA), an application specific integrated circuit (ASIC), control circuitry on a memory die, etc.), or other suitable processor. In one embodiment, the control circuitry 206 can include a processor configured to execute instructions stored in memory to perform various processes, logic flows, and routines for controlling operation of the memory device 200, including managing the main memory 202 and handling communications between the memory device 200 and the host device 208. In some embodiments, the control circuitry 206 can include embedded memory with memory registers for storing (e.g., memory addresses, row counters, bank counters, memory pointers, fetched data, etc.) In another embodiment of the present technology, a memory device 200 may not include control circuitry, and may instead rely upon external control (e.g., provided by the host device 208, or by a processor or controller separate from the memory device 200).

The host device 208 can be any one of a number of electronic devices capable of utilizing memory for the temporary or persistent storage of information, or a component thereof. For example, the host device 208 may be a computing device, such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device 208 may be a networking device (e.g., a switch, a router, etc.) or a recorder of digital images, audio and/or video, a vehicle, an appliance, a toy, or any one of a number of other products. In one embodiment, the host device 208 may be connected directly to memory device 200, although in other embodiments, the host device 208 may be indirectly connected to memory device 200 (e.g., over a networked connection or through intermediary devices).

In operation, the control circuitry 206 can directly write or otherwise program (e.g., erase) the various memory regions of the main memory 202. The control circuitry 206 communicates with the host device 208 over a host device bus or interface 210. In some embodiments, the host device 208 and the control circuitry 206 can communicate over a dedicated memory bus (e.g., a DRAM bus). In other embodiments, the host device 208 and the control circuitry 206 can communicate over a serial interface, such as a serial attached SCSI (SAS), a serial AT attachment (SATA) interface, a peripheral component interconnect express (PCIe), or other suitable interface (e.g., a parallel interface). The host device 208 can send various requests (in the form of, e.g., a packet or stream of packets) to the control circuitry 206. A request can include a command to read, write, erase, return information, and/or to perform a particular operation (e.g., a refresh operation, a TRIM operation, a precharge operation, an activate operation, a wear-leveling operation, a garbage collection operation, etc.).

### Temperature-Based Masking Circuit

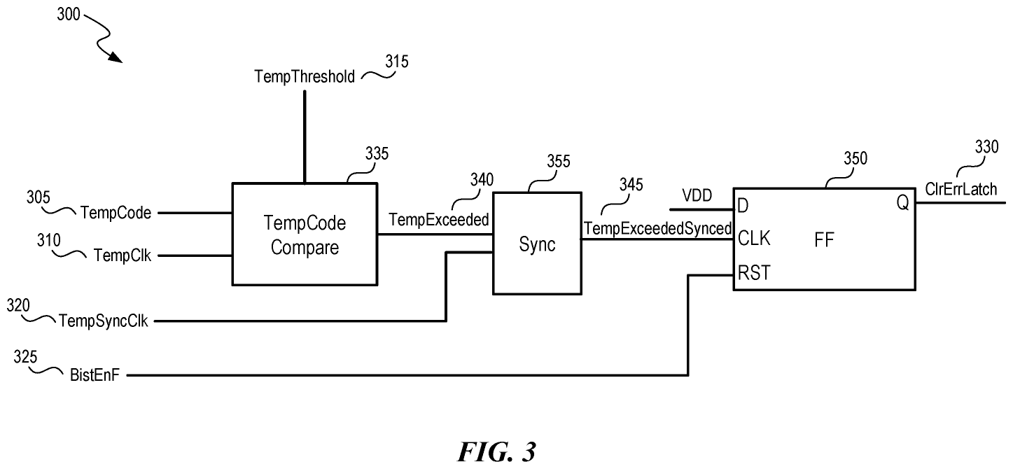

FIG. 3 is a simplified block diagram schematically illustrating a temperature-based masking circuit 300 in accordance with embodiments of the present technology. The temperature-based masking circuit 300 can be configured to control the masking of errors identified by an mBIST circuit during a self-test. In some embodiments, the temperature-based masking circuit 300 can be implemented within the mBIST circuit 190, the mBIST error masking circuit 192, or coupled between the mBIST circuit 190 and the mBIST error masking circuit 192.

The temperature-based masking circuit 300 can include logic devices (e.g., buffers, delays, flip-flops, NOT gates, NAND gates, NOR gates, XNOR gates, AND gates, OR gates, XOR gates, or a combination thereof) and circuits configured to control error masking during mBIST operation. For example, the temperature-based masking circuit 300 can receive input/status signals, such as TempCode 305, TempClk 310, TempThreshold 315, TempSyncClk 320, and/or BistEnF 325 to monitor operating conditions (e.g., temperature) during mBIST operations and determine whether any self-test errors should be masked. The temperature-based masking circuit 300 can generate a clear signal (e.g., ClrErrLatch 330) based on the input/status signals. The generated clear signal can control other portions of the apparatus 100 of FIG. 1 (e.g., the mBIST circuit 190), including whether test results and/or error information will be stored during mBIST operation. For example, ClrErrLatch 330 can be used to hold mBIST error latches in a reset state, such that the error latches do not record test results.

Temperature-based masking circuit 300 input signals TempCode 305 and TempClk 310 can be generated by a temperature sensor (e.g., temperature sensor 194 of FIG. 1). TempClk 310 indicates when TempCode 305 is valid. For example, in some embodiments TempCode 305 is valid when TempClk 310 pulses high. TempCode 305 indicates the temperature detected at the temperature sensor. In some embodiments, the temperature sensor updates TempCode 305 at normal intervals (e.g., every 1 ms). In some embodiments, TempCode 305 encodes (e.g., in a binary value) the detected temperature. In some embodiments, TempCode 305 encodes what range of temperatures the detected temperature falls in. Table 1, below, illustrates an example encoding of a 3-bit TempCode 305.

TABLE 1
Example TempCode Encodings

| TempCode Encoding | Detected Temperature |
|---|---|
| 3′b000 | 34° C. or less |
| 3′b001 | 35° C. to 49° C. |
| 3′b010 | 50° C. to 64° C. |
| 3′b011 | 65° C. to 79° C. |
| 3′b100 | 80° C. to 94° C. |
| 3′b101 | 95° C. to 109° C. |
| 3′b110 | 110° C. to 124° C. |
| 3′b111 | 125° C. or greater |

Temperature-based masking circuit 300 input signal TempThreshold 315 indicates the threshold temperature at which (or above) mBIST errors are to be masked. TempThreshold 315 can be generated, for example, by mBIST circuit 190, mBIST error masking circuit 192, command decoder 115, and/or input/output circuit 160 of FIG. 1. In some embodiments TempThreshold 315 is configurable to different thresholds depending on the apparatus 100. TempThreshold 315 can be encoded in the same manner as TempCode 305 so that, as described herein, the detected temperature encoded in TempCode and the threshold temperature encoded in TempThreshold can be compared to each other. In some embodiments, TempThreshold 315 is encoded with a threshold temperature of 125° C.

The temperature-based masking circuit 300 includes logic, illustrated as TempCode Compare 335 in FIG. 3, that determines whether the detected temperature encoded in TempCode 305 equals or exceeds the threshold temperature encoded in TempThreshold 315. In some embodiments, TempCode Compare 335 is implemented with combinational logic. For example, TempCode Compare 335 can be implemented with combinational logic that determines whether TempCode 305 matches a threshold temperature encoded in TempThreshold 315. As a further example, TempCode Compare 335 can be implemented with combinational logic that determines whether TempCode 305 exceeds a threshold temperature encoded in TempThreshold 315. When the detected temperature equals or exceeds the threshold temperature (as encoded in TempCode 305 and TempThreshold 315, respectively), TempCode Compare 335 asserts TempExceeded 340. In some embodiments, TempCode Compare 335 asserts TempExceeded 340 when the detected temperature is 125° C. or greater.

Temperature-based masking circuit 300 input signal TempSyncClk 320 and component Synchronizer 355 can be used to synchronize signals between the temperature sensor and mBIST circuits. For example, in some embodiments the temperature sensor's clock signal (e.g., TempClk 310) is not synchronized with the clock signal used by different mBIST circuits (e.g., mBIST circuit 190 and/or mBIST error masking circuit 192). As a result, a value generated in the clock domain of the temperature sensor, such as TempCode 305 and/or TempExceeded 340, may not be stable when sampled in the clock domain of mBIST circuit 190 and/or mBIST error masking circuit 192. Therefore, TempSyncClk 320 and Synchronizer 355 can be used to generate signals that are stable in the mBIST clock domain based on signals generated in the temperature sensor clock domain. In some embodiments, TempSyncClk 320 is based on a clock signal in the mBIST clock domain, and may toggle during mBIST operations as the temperature-based masking circuit 300 performs a temperature check. Synchronizer 355 can sample TempExceeded 340, and evaluate when it is stable (e.g., unchanged) for a threshold number of consecutive number of clock cycles of TempSyncClk 320. For example, Synchronizer 355 can determine whether TempExceeded 340 is stable for 2 consecutive clock cycles of TempSyncClk 320. As a further example, Synchronizer 355 can determine whether TempExceeded 340 is stable for 10 consecutive clock cycles of TempSyncClk 320. Based on the determination that TempExceeded 340 is stable, Synchronizer 355 generates a signal TempExceededSynced 345 that is synchronized to the mBIST clock domain. For example, TempExceeded 340 may toggle (e.g., assert), but the Synchronizer 355 may not toggle TempExceededSynced 345 until TempExceeded remains stable for a threshold number of TempSyncClk 320 clock cycles. In some embodiments, Synchronizer 355 is implemented with a combination of combinational logic and/or sequential logic. For example, the Synchronizer 355 can be implemented with state indicating the values of TempExceeded 340 in some prior clock cycles of TempSyncClk 320 and logic to evaluate whether a present value of TempExceeded matches the values saved in the state. It will be appreciated that other techniques may be used by the temperature-based masking circuit 300 to synchronize TempCode 305 and/or TempExceeded 340 to the mBIST clock domain. In some embodiments of the present technology, synchronization by the temperature-based masking circuit 300 between different clock domains is not needed. For example, a temperature sensor clock domain and an mBIST clock domain may already be synchronized. As a further example, input signals received by the temperature-based masking circuit 300 may already be synchronized. In some embodiments the temperature-based masking circuit 300 does not include a Synchronizer 355, and TempExceeded 340 can be used in place of TempExceededSynced 345.

Temperature-based masking circuit 300 includes flip-flop 350, which generates output signal ClrErrLatch 330 based on TempExceededSynced 345. In some embodiments, TempExceededSynced 345 is coupled to the CLK input of the flip-flop 350, and the D input of the flip-flop 350 is coupled to VDD. In said embodiments, once TempExceededSynced 345 asserts, the output of flip-flop 350 (ClrErrLatch 330) goes high (e.g., to VDD) and remains asserted for the rest of an mBIST pattern, until the flop-flop is reset. As described herein, ClrErrLatch 330 can be used to reset mBIST error latches, and therefore once TempExceededSynced 345 asserts, in said embodiments the mBIST error latches remain in reset for the duration of an mBIST pattern until the flip-flop 350 is reset. In some embodiments input signal BistEnF 325, which asserts when mBIST is not running, can be coupled to the RST input of flip-flop 350. Therefore, the flip-flop 350 can be held in a reset state when mBIST is not running, and reset every mBIST run (thereby de-asserting ClrErrLatch 330, if it was previously asserted).

Although FIG. 3 illustrates an embodiment of the temperature-based masking circuit 300 that receives TempThreshold 315 as an input, in some embodiments the temperature threshold is hardcoded (e.g., through the implementation of TempCode Compare 335). For example, TempCode Compare 335 can be implemented to assert TempExceeded 340 whenever a valid TempCode 305 exceeds 125° C.

In some embodiments, temperature-based masking circuit 300 includes additional logic devices to generate TempSyncClk 320 locally instead of receiving it as an input. For example, temperature-based masking circuit 300 can include logic to detect when TempCode 305 is stable (e.g., does not change values) for two consecutive clock cycles, after which it asserts TempSyncClk 320.

In some embodiments, the output ClrErrLatch 330 is stored in a status register (not shown) instead of, or in addition to, using it to hold mBIST error latches in reset. The status register can be accessible to a user of the apparatus 100.

Flow for Temperature-Based mBIST Error Masking

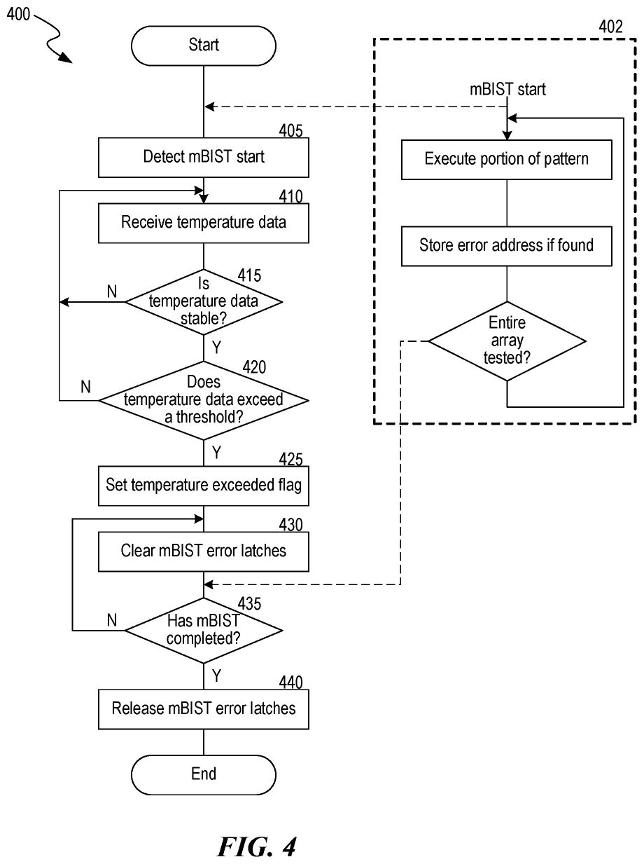

FIG. 4 is a flow diagram illustrating a process 400 for masking errors, based on temperature, during mBIST operation, in accordance with embodiments of the present technology. Aspects of the process 400 can be performed, for example, by the apparatus 100 of FIG. 1 (including mBIST circuit 190, mBIST error masking circuit 192, and/or temperature sensor 194), the temperature-based masking circuit 300 of FIG. 3, or a combination thereof.

As illustrated in FIG. 4 and described herein, the process 400 for masking errors based on temperature can be performed in parallel with an mBIST operation 402. The mBIST operation 402 can be initiated and/or controlled by a component of the apparatus 100, for example, mBIST circuit 190, to perform a self-test on another component of the apparatus, such as the memory array 150. As described herein, during the mBIST operation, an mBIST test sequence can perform controlled writes to and reads from the memory being tested to detect errors in the memory. The test results characterizing the results of those tests, which can include information such as the locations in memory where errors were detected and the types of errors detected, can be saved to mBIST error latches under control of the apparatus (e.g., mBIST circuit 190). As illustrated, the mBIST operation 402 can comprise various steps to test the memory. For example, the mBIST operation 402 can include executing a portion of an mBIST test pattern on the memory, and storing the memory address of any errors found. The mBIST operation 402 can further include determining whether the entire memory array has been tested, and if not, looping to execute other portions of the mBIST test pattern to test the entire memory array. When the entire memory array has been tested, the mBIST operation 402 can be completed. As illustrated in FIG. 4, and as described herein, while the mBIST operation 402 is being performed the process 400 can be performed continually and/or periodically to sample temperature data while the mBIST pattern is running.

The process 400 begins at block 405, where the process detects the start of the mBIST operation 402 used to test a memory. The process 400 can detect the start of the mBIST operation 402 based on a change in value of a signal, such as BistEnF 325 illustrated in FIG. 3.

At block 410, the process 400 receives temperature data characterizing the temperature of the memory under test. For example, the temperature data may be generated by an on-die temperature sensor of the apparatus 100 (such as temperature sensor 194), and can characterize the temperature of the apparatus and/or memory array 150. In some embodiments, the temperature data indicates the specific temperature detected by the temperature sensor. In some embodiments, the temperature data indicate in what range of temperatures the detected temperature falls in. In some embodiments, the temperature data additionally includes an indication of whether the temperature data is valid (e.g., in the form of a clock signal, valid signal, etc.).

At decision block 415, the process 400 determines whether the received temperature data is stable. To determine whether the temperature data is stable, the process 400 can evaluate whether the temperature data has not changed for a threshold number of clock cycles (e.g., of a clock signal associated with the temperature data and/or a clock signal associated with the mBIST operation). In some embodiments, the process 400 determines the temperature data is stable if it has not changed after two consecutive cycles. In some embodiments, the process 400 determines that the temperature data is stable, even if the temperature data has changed, as long as the change is less than a threshold amount (e.g., less than 5° C.). If the process 400 determines that the temperature data is not stable (e.g., it changed in fewer than a threshold number of clock cycles and/or changed by more than a threshold amount), then in some embodiments the process returns to block 410 to receive additional temperature data (e.g., in a subsequent clock cycle). If the process 400 determines that the temperature data is not stable, then in some embodiments the process returns to decision block 415 to evaluate again (e.g., in a subsequent clock cycle) whether the temperature data is stable. If the process 400 determines that the temperature data is stable, then the process continues to decision block 420.

At decision block 420, the process 400 determines whether the temperature data exceeds a temperature threshold. For example, the process 400 can determine whether the temperature data exceeds a threshold of 125° C. In some embodiments, the temperature threshold is a fixed value. In some embodiments, the temperature threshold is a configurable parameter (e.g., set by a component of the apparatus) and received by the process 400 (not shown). If the process 400 determines that the temperature data does not exceed the temperature threshold, then the process returns to block 410 to receive additional temperature data. If the process 400 determines that the temperature does exceed the temperature threshold, then the process continues to block 425.

At block 425, the process 400 sets a flag indicating that the threshold temperature was exceeded by the apparatus during the mBIST operation. The flag can be used, for example, by a customer using the apparatus to let them know that the apparatus hit an operating temperature limit. In some embodiments the process sets the temperature exceeded flag in a memory location, status register, and/or other state visible to the customer.

At block 430, the process 400 clears and/or deactivates the mBIST error latches used to store test results generated by the mBIST operation. For example, the process 400 can assert a reset signal coupled to the mBIST error latches, which clears the contents of the mBIST error latches. As a further example, the process 400 can force values onto the data input of the mBIST error latches that indicate no error information (e.g., all zeroes), and then clear an enable input to the mBIST error latches (so that no new data is written) after the values have been written. As described herein, by clearing the mBIST error latches, the process 400 in effect masks or ignores the mBIST results generated while the temperature threshold was exceeded.

At decision block 435, the process 400 determines whether the mBIST operation has completed. The completion of the mBIST operation can be indicated by a signal from a component of the apparatus 100, such as mBIST circuit 190. For example, the process 400 can determine whether the mBIST operation has completed based on a change in value of the BistEnF 325 illustrated in FIG. 3. If the process 400 determines that the mBIST operation has not completed, the process returns to block 430 where the process continues to clear and/or deactivate the mBIST error latches (e.g., hold the latches in reset) for the duration of the mBIST operation. If the process 400 determines that the mBIST operation has completed, the process continues to block 440.

At block 440, the process 400 releases the mBIST error latches from the cleared and/or deactivated state. For example, the process 400 can de-assert a reset signal coupled to the mBIST error latches. By releasing the mBIST error latches from reset, the mBIST error latches can be used during a subsequent mBIST operation to record test rules generated by that operation. The process 400 then ends.

While FIG. 4 illustrates an embodiment of process 400 in which the mBIST error latches are activated after the mBIST operation ends, in some embodiments the error latches remain inactivated until a subsequent event re-activates them. For example, the mBIST error latches can be reactivated at the start of the next mBIST operation.

Illustration of Temperature-based mBIST Error Masking

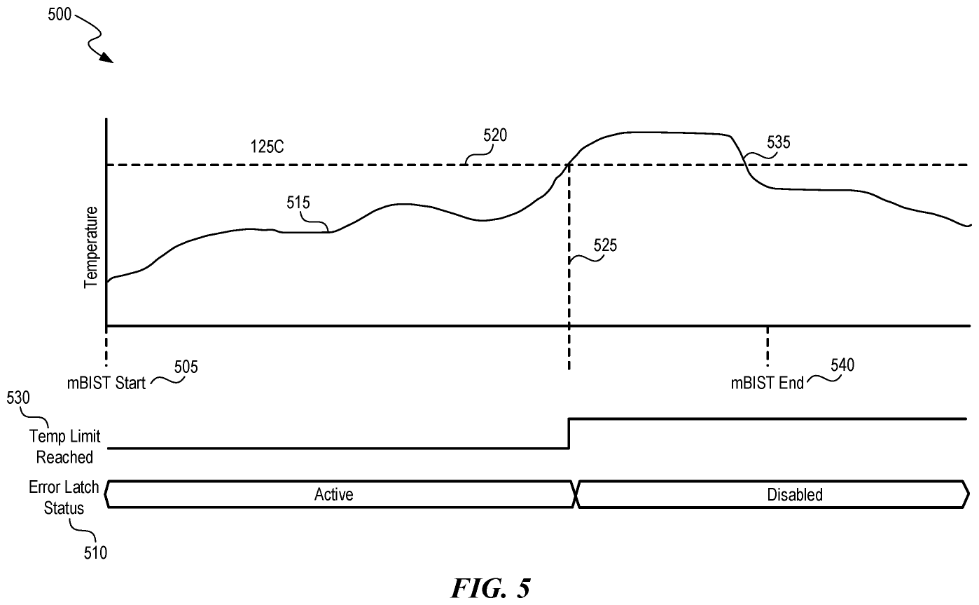

FIG. 5 is a waveform diagram 500 illustrating error masking during an mBIST operation in accordance with embodiments of the present technology. At a time indicated by mBIST start 505, an mBIST operation begins. As indicated by Error Latch Status 510, at the same time as mBIST start 505, corresponding mBIST error latches go active. That is, for example, mBIST error latches are enabled to capture test results generated during the mBIST operation.

While the mBIST operation is ongoing, a temperature 515 (e.g., associated with a device under test by the mBIST operation, such as a memory array) is monitored. The temperature 515 can be monitored, for example, using an on-die sensor. As illustrated by the waveform diagram 500, the temperature 515 can change over time, and can approach a temperature threshold 520. As described herein, the temperature threshold 520 can represent the temperature at which point the device under test (e.g., the memory array) is not stable for testing by the mBIST operation. For example, the temperature threshold 520 can characterize a temperature at which point a memory array does not retain stored values long enough for an mBIST operation to complete successfully (due, for example, to a reduced retention time requiring a more frequent refresh). In the embodiment illustrated in FIG. 5, the temperature threshold 520 is 125° C.

At a time 525, the temperature 515 increases and exceeds the temperature threshold 520. Because the temperature threshold 520 has been exceeded at approximately the time 525, a Temp Limit Reached signal 530 (e.g., TempExceededSynced 345 or ClrErrLatch 330, illustrated in FIG. 3) asserts. The Temp Limit Reached signal 530 can be used, for example, as an input to downstream logic, as a flag visible to a user of the device under test (e.g., as stored in a status register), etc. Additionally, at approximately the time 525, the Error Latch Status 510 changes to disabled. That is, as described herein, the mBIST error latches used to capture test results are disabled so that no new data (such as test result data generating during the mBIST operation) can be written to the mBIST error latches and/or the mBIST error latches are cleared so that no existing test result data remains resident in the latches. It will be appreciated that the changes to Error Latch Status 510 and the Temp Limit Reached signal 530 are described herein as occurring at approximately the time 525 to reflect the fact that in some embodiments a delay may occur between when the temperature 515 exceeds the temperature threshold 520, and when Error Latch Status and the Temp Limit Reached signal change (e.g., due to propagation delay, gate delay, clock cycles, etc.).

At a time 535, the temperature 515 decreases and no longer exceeds the temperature threshold 520. As illustrated in the waveform diagram 500, the Temp Limit Reached signal 530 remains asserted, and Error Latch Status 510 remains at disabled, even after the temperature 515 has dropped below the temperature threshold 520. That is, the Temp Limit Reached signal 530 can remain asserted and Error Latch Status 510 can remain at disabled for at least the remainder of the duration of the mBIST operation, the end of which is at a time indicated by mBIST end 540. In the embodiment illustrated in FIG. 5, Temp Limit Reached signal 530 remains asserted and Error Latch Status 510 remains disabled even after mBIST end 540, and can remain in those states until the start of a next mBIST operation. In some embodiments, the Temp Limit Reached signal 530 can de-assert and/or Error Latch Status 510 can change to active upon mBIST end 540.

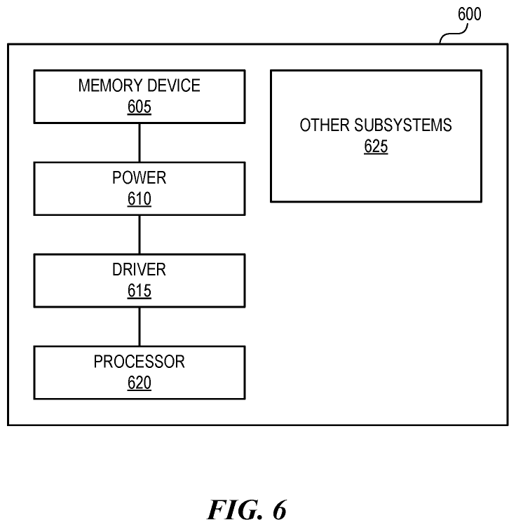

FIG. 6 is a schematic view of a system 600 that includes an apparatus in accordance with embodiments of the present technology. Any one of the foregoing apparatuses (e.g., memory devices) described above with reference to FIGS. 1-5 can be incorporated into any of a myriad of larger and/or more complex systems, a representative example of which is system 600 shown schematically in FIG. 6. The system 600 can include a memory device 605, a power source 610, a driver 615, a processor 620, and/or other subsystems or components 625. The memory device 605 can include features generally similar to those of the apparatus described above with reference to FIGS. 1-5, and can therefore include various features for performing a direct read request from a host device. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, vehicles, appliances and other products. Components of the system 600 may be housed in a single unit or distributed over multiple, interconnected units (e.g., through a communications network). The components of the system 600 can also include remote devices and any of a wide variety of computer readable media.

It should be noted that the methods described above describe possible implementations, and that the operations and the steps may be rearranged or otherwise modified and that other implementations are possible. Furthermore, embodiments from two or more of the methods may be combined.

Although in the foregoing example embodiments, memory modules and devices have been illustrated and described with respect to DRAM devices, embodiments of the present technology may have application to other memory technologies, including SRAM, SDRAM, NAND and/or NOR flash, PCM, magnetic RAM (MRAM), ferroelectric RAM (FeRAM), etc. Moreover, although memory modules have been illustrated and described as dual in-line memory modules (DIMMs) having nine memory devices, embodiments of the disclosure may include more or fewer memory devices, and/or involve other memory module or package formats (e.g., single in-line memory modules (SIMMs), small outline DIMMS (SODIMMs), single in-line pin packages (SIPPs), custom memory packages, etc.).

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

I/We claim:

1. An apparatus, comprising:
a functional circuit configured to provide a set of functions;
a data storing device configurable to store a self-test result;
a built-in self-test (BIST) circuit coupled to the functional circuit and the data storing device, the BIST circuit configured to implement a self-test using the functional circuit and to generate the self-test result; and
an error masking circuit coupled to the data storing device, the error masking circuit configured to:
receive temperature data characterizing a temperature of the functional circuit,
determine whether the temperature data exceeds a temperature threshold, and
store, based on whether the temperature data exceeds the temperature threshold, the self-test result in the data storing device.

2. The apparatus of claim 1, wherein
the functional circuit includes a memory array configured to store data and provide access to the stored data;
the BIST circuit is a memory BIST (mBIST) circuit;
the self-test corresponds to (1) writing predetermined data and (2) reading the written data using one or more known locations in the memory array to test functionalities of the memory array; and
the self-test result is based on reading the written data from the one or more known locations.

3. The apparatus of claim 1, wherein the apparatus further comprises an on-die temperature sensor configured to generate the temperature data.

4. The apparatus of claim 1, wherein the error masking circuit is further configured to deactivate the data storing device when the temperature data exceeds the temperature threshold.

5. The apparatus of claim 4, wherein deactivating the data storing device comprises asserting a reset signal coupled to the data storing device, and wherein asserting the reset signal clears the data storing device.

6. The apparatus of claim 4, wherein the error masking circuit is further configured to:
receive additional temperature data, and
maintain the deactivation of the data storing device, if the additional temperature data does not exceed the threshold temperature, during the self-test.

7. The apparatus of claim 1, the apparatus further comprising a repair resource coupled to the data storing device and the functional circuit, wherein the repair resource is configured to repair the functional circuit based on the self-test result stored in the data storing device.

8. The apparatus of claim 1, wherein the temperature data is associated with a first clock domain, the data storing device is associated with a second clock domain, and the error masking circuit is further configured to synchronize the temperature data to the second clock domain.

9. The apparatus of claim 8, wherein the error masking circuit is further configured to:
receive a synchronization signal, and
wherein the synchronization of the temperature data to the second clock domain is based on the synchronization signal.

10. The apparatus of claim 9, wherein the synchronization signal characterizes whether the temperature data has been stable for two clock cycles in the second clock domain.

11. The apparatus of claim 1, wherein the threshold temperature characterizes a maximum operating temperature of the apparatus.

12. The apparatus of claim 1, wherein the apparatus further comprises a status register configured to store a flag indicating the apparatus has exceeded a temperature limit, and wherein the error masking circuit is further configured to generate the flag based on the determination of whether the temperature data exceeds the temperature threshold.

13. The apparatus of claim 12, wherein the status register is accessible to a user of the apparatus.

14. A method of operating an apparatus that includes a functional circuit configured to provide a set of functions, the method comprising:
initiating a self-test of the functional circuit using a built-in self-test (BIST) circuit coupled to the functional circuit, wherein the self-test corresponds to performing the set of functions according to a predetermined sequence and a predetermined input set;
at a data storing device, receiving a set of results generated by and during the self-test;
receiving temperature data characterizing the temperature of the functional circuit; and
deactivating the data storing device during one or more portions of the self-test, to prevent saving of the set of results by the data storing device during the one or more portions, based on the temperature data.

15. The method of claim 14, wherein the method further comprises receiving a temperature threshold, and wherein the deactivating of the data storing device is based further on the temperature threshold.

16. The method of claim 15, wherein deactivating the data storing device comprises:
determining whether the temperature data exceeds the temperature threshold; and
asserting an error reset signal, coupled to the data storing device, based on the determination that the temperature data exceeds the temperature threshold.

17. The method of claim 14, wherein the temperature data is associated with a first clock domain, the data storing device is associated with a second clock domain, and the method further comprises synchronizing the temperature data to the second clock domain.

18. The method of claim 14, the method further comprising:
receiving, after the deactivating of the data storing device, second temperature data, wherein the second temperature data does not exceed the temperature threshold; and
maintaining the deactivating of the data storing device during the one or more portions of the self-test.

19. An apparatus, comprising:
a functional circuit;
an error storing circuit; and
a built-in self-test (BIST) circuit configured to:
execute a self-test using the functional circuit to generate a self-test result; and
control whether the error storing circuit stores the self-test result or not based on temperature data.

20. The apparatus of claim 19, wherein the functional circuit is a memory array comprised of dynamic random access memory (DRAM).
